(19) United States
(12) Patent Application Publication
(10) Pub. No.: US 2016/0219692 A1
(43) Pub. Date: Jul. 28, 2016

(54) CIRCUIT BOARD OF ELECTRICAL CONNECTOR

(71) Applicant: ALL BEST PRECISION TECHNOLOGY CO., LTD., Taoyuan County (TW)

(72) Inventor: HAVEN YANG, New Taipei City (TW)

(21) Appl. No.: 14/605,372

(22) Filed: Jan. 26, 2015

(51) Int. Cl. H05K 1/02; H05K 1/03

(52) U.S. Cl. CPC H05K 1/0271; H05K 1/0326; H05K 1/0346; H05K 1/0298; H05K 1/0245

(57) ABSTRACT

A circuit board of an electrical connector includes a substrate having an electrical contact region, high-frequency line soldering region, opening, and low-frequency region, with the electrical contact region electrically connected to the low-frequency region; and a high-frequency wiring having a high-frequency electrical contact end and a high-frequency line soldering end, with the high-frequency electrical contact ends disposed at the electrical contact region and the high-frequency line soldering ends disposed at the high-frequency line soldering region. Another circuit board of an electrical connector includes a substrate having a transverse substrate and a longitudinal substrate connected to assume a T-shaped configuration; the substrate is flanked by two corners; the transverse substrate has an electrical contact region and a high-frequency line soldering region; the longitudinal substrate has low-frequency regions; and the electrical contact region is electrically connected to the low-frequency regions. The circuit boards shorten high-frequency wirings, thereby decreasing attenuation.

### FIELD OF THE INVENTION

The present invention relates to circuit boards of an electrical connector, and more particularly, to a circuit board disposed in an electrical connector and adapted to not only shorten high-frequency wirings to thereby decrease attenuation but also prevent the circuit board from warping when high-frequency lines are soldered to the circuit board.

### BACKGROUND OF THE INVENTION

An electrical connector is a conductor device for transmitting electronic data. It is widely used in a wide variety of transmission wirings. A connection formed from the electrical connector is temporary and easy to plug and unplug at any time. Alternatively, the connection formed from the electrical connector is a permanent contact between transmission apparatuses. The electrical connector comes in different forms, including PCB connector, rectangular I/O, circular I/O, CPU socket, RF coax, fiber optic connector, and high-voltage connector. In Taiwan, the electrical connector is primarily available in the form of PCB connector and rectangular I/O. The electrical connector in wide use is characterized in that the electrical connector has therein a circuit board in order to be inserted into an electrical connector slot and that the circuit board is in electrical contact with conductive pins in the electrical connector slot so as to transmit electronic data between electronic apparatuses.

Referring to FIG. 1, a conventional circuit board of an electrical connector has a substrate 9, a plurality of high-frequency wirings 94, and a plurality of low-frequency wirings 95. The substrate 9 has an electrical contact region 91, a low-frequency region 93, and a high-frequency line soldering region 92 which are arranged successively and longitudinally. The electrical contact region 91 is disposed at the upper edge of the substrate 9. The high-frequency line soldering region 92 is disposed at the lower edge of the substrate 9. The low-frequency region 93 is centrally disposed at the substrate 9. The high-frequency wirings 94 each have a high-frequency electrical contact end 941 and a high-frequency line soldering end 942. The high-frequency wirings 94 are disposed at the substrate 9 and pass the low-frequency region 93 laterally. The high-frequency electrical contact end 941 is disposed at the electrical contact region 91, and the high-frequency line soldering end 942 is disposed at the high-frequency line soldering region 92. The low-frequency wirings 95 each have a low-frequency electrical contact end 951 and a low-frequency electrical connection end 952. The low-frequency wirings 95 are disposed at the substrate 9. The low-frequency electrical contact end 951 is disposed at the electrical contact region 91. The low-frequency electrical connection end 952 is disposed at the low-frequency region 93. As described before, since the low-frequency region 93 of the circuit board of the conventional electrical connector is centrally disposed at the substrate 9, routes of the high-frequency wirings 94 are lengthened to thereby increase attenuation. Accordingly, the present invention provides a circuit board disposed in an electrical connector and adapted to not only shorten high-frequency wirings to thereby decrease attenuation but also prevent the circuit board from warping when high-frequency lines are soldered to the circuit board.

### SUMMARY OF THE INVENTION

In view of the aforesaid drawbacks of the prior art, the inventor of the present invention conceived room for improvement in the prior art and thus conducted extensive researches and experiments according to the inventor's years of experience in the related industry, and finally developed a circuit board of an electrical connector to not only shorten high-frequency wirings and thereby decrease attenuation but also prevent the circuit board from warping when high-frequency lines are soldered to the circuit board.

In order to achieve the above and other objectives, the first aspect of the present invention provides a circuit board of an electrical connector, comprising: a substrate having an electrical contact region, a high-frequency line soldering region, at least an opening, and a low-frequency region which are arranged successively and longitudinally, wherein the electrical contact region is disposed at the edge of the substrate, and the electrical contact region is electrically connected to the low-frequency region; and a plurality of high-frequency wirings each having a high-frequency electrical contact end and a high-frequency line soldering end, wherein the high-frequency wirings are disposed at the substrate, wherein the high-frequency electrical contact ends are disposed at the electrical contact region, and the high-frequency line soldering ends are disposed at the high-frequency line soldering region.

The circuit board of the first aspect of the present invention further comprises a plurality of low-frequency wirings each having a low-frequency electrical contact end and a low-frequency electrical connection end. The low-frequency wirings are disposed at the substrate and pass the openings laterally. The low-frequency electrical contact ends are disposed at the electrical contact region. The low-frequency electrical connection ends are disposed at the low-frequency region.

Regarding the circuit board of the first aspect of the present invention, the openings are in the number of two and are arranged transversely, whereas the low-frequency wirings pass between the openings, thereby defining the second aspect of the present invention.

Regarding the circuit board of the first aspect of the present invention, the high-frequency electrical contact ends and the low-frequency electrical contact ends are arranged transversely and at intervals, and the high-frequency line soldering ends are arranged transversely and at intervals.

The circuit board of the first aspect of the present invention further comprises a plurality of high-frequency lines each having a signal line and an insulating coating. The insulating coatings enclose the signal lines, respectively. The end portions of the signal lines are exposed from the end portions of the insulating coatings, respectively. The end portions of the signal lines are flatly soldered to the high-frequency line soldering ends, respectively. The end portions of the insulating coatings are partially disposed in the openings, respectively.

The third aspect of the present invention provides a circuit board of an electrical connector, comprising: a substrate having a transverse substrate and a longitudinal substrate connected to each other to form a T-shaped configuration, wherein the substrate is flanked by two corners, wherein the transverse substrate has thereon an electrical contact region and a high-frequency line soldering region longitudinally, with the electrical contact region disposed at the edge of the transverse substrate, wherein the longitudinal substrate has a low-frequency region, with the high-frequency line soldering region disposed between the electrical contact region and the low-frequency region, wherein the electrical contact region is electrically connected to the low-frequency region; and a plurality of high-frequency wirings each having a high-frequency electrical contact end and a high-frequency line soldering end, with the high-frequency wirings disposed at the transverse substrate, and the high-frequency electrical contact ends disposed at the electrical contact region, wherein the high-frequency line soldering ends are disposed at the high-frequency line soldering region.

The circuit board of the third aspect of the present invention further comprises a plurality of low-frequency wirings each having a low-frequency electrical contact end and a low-frequency electrical connection end. The low-frequency wirings are disposed at the substrate and pass between the corners. The low-frequency electrical contact ends are disposed at the electrical contact region. The low-frequency electrical connection ends are disposed at the low-frequency region.

Regarding the circuit board of the third aspect of the present invention, the high-frequency electrical contact ends and the low-frequency electrical contact ends are arranged transversely and at intervals. The high-frequency line soldering ends are arranged transversely and at intervals.

The circuit board of the third aspect of the present invention further comprises a plurality of high-frequency lines each having a signal line and an insulating coating. The insulating coatings enclose the signal lines, respectively. The end portions of the signal lines are exposed from the end portions of the insulating coatings, respectively. The end portions of the signal lines are flatly soldered to the high-frequency line soldering ends, respectively. The end portions of the insulating coatings are partially disposed in the corners, respectively.

Accordingly, the circuit boards of the present invention not only shorten high-frequency wirings to thereby decrease attenuation but also prevent the circuit boards from warping when the high-frequency lines are soldered to the circuit boards.

### BRIEF DESCRIPTION OF THE DRAWINGS

FIG. 1 (PRIOR ART) is a schematic view of a conventional circuit board of an electrical connector;

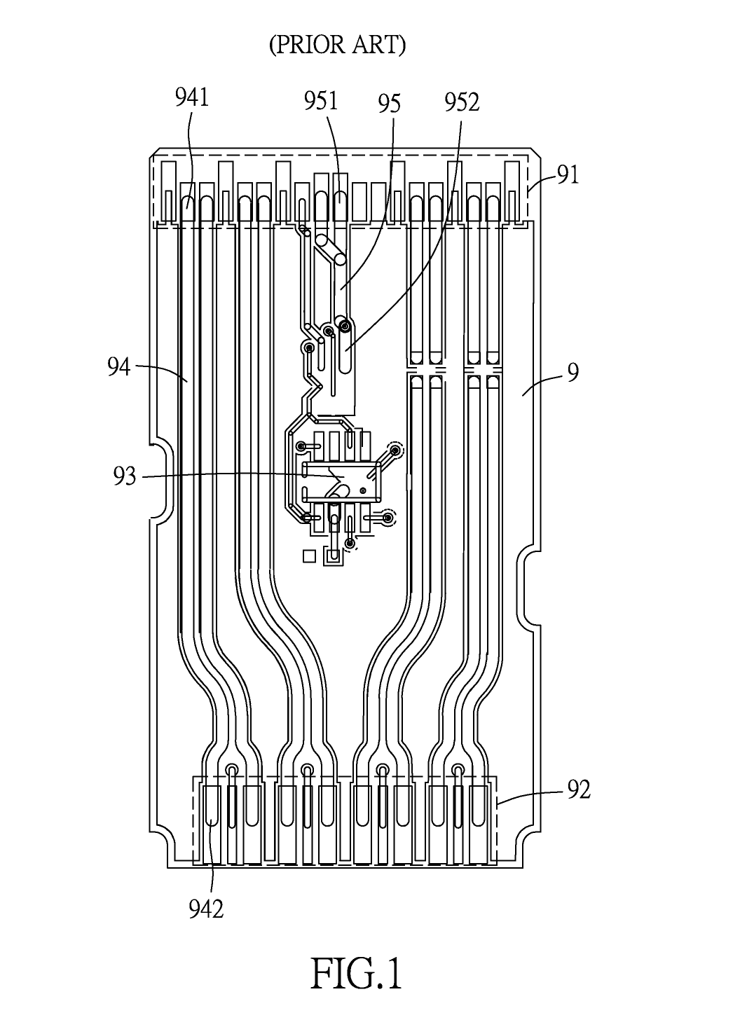

FIG. 2 is a schematic view of a circuit board according to the first embodiment of the present invention;

FIG. 3 is a schematic view of the circuit board electrically connected to high-frequency lines according to the first embodiment of the present invention;

FIG. 4 is a cross-sectional view of implementation of the high-frequency lines of the circuit board according to the first embodiment of the present invention;

FIG. 5 is a schematic view of a circuit board according to the second embodiment of the present invention;

FIG. 6 is a schematic view of the circuit board electrically connected to high-frequency lines according to the second embodiment of the present invention;

FIG. 7 is a cross-sectional view of implementation of the high-frequency lines of the circuit board according to the second embodiment of the present invention;

FIG. 8 is a schematic view of a circuit board according to the third embodiment of the present invention;

FIG. 9 is a schematic view of the circuit board electrically connected to high-frequency lines according to the third embodiment of the present invention;

FIG. 10 is a cross-sectional view of implementation of the high-frequency lines of the circuit board according to the third embodiment of the present invention;

FIG. 11 is an exploded view of an embodiment of the present invention applicable to an electrical connector; and

FIG. 12 is an assembly schematic view of an embodiment of the present invention applicable to an electrical connector.

### DETAILED DESCRIPTION OF THE PREFERRED EMBODIMENTS

To enable persons skilled in the art to gain insight into the objectives, technical features, and advantages of the present invention and implement the present invention accordingly, the technical features and implementation of the present invention are hereunder illustrated with drawings and preferred embodiments. However, the preferred embodiments are not restrictive of the present invention, and the drawings are schematic of the features of the present invention.

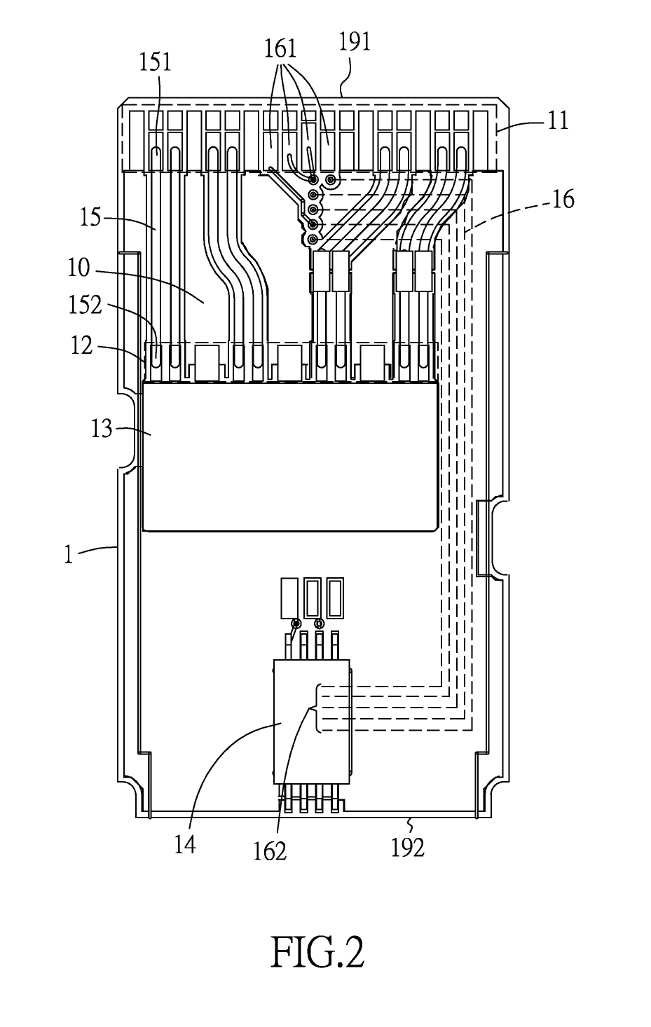

Referring to FIG. 2, the first aspect of the present invention provides a circuit board of an electrical connector. The circuit board comprises a substrate 1 and a plurality of high-frequency wirings 15. The substrate 1 is a bakelite board, fiberglass board, or plastic board, is multilayer, and has at least a middle layer. A plurality of low-frequency wirings 16 is embedded in the middle layer. The substrate 1 has on its surface 10 an electrical contact region 11, a high-frequency line soldering region 12, an opening 13, and a low-frequency region 14 which are arranged successively and longitudinally (that is, in the direction from the upper edge 191 to the lower edge 192 of the substrate 1, as shown in FIG. 2). The electrical contact region 11 is disposed at the upper edge 191 of the surface 10 of the substrate 1 so as to be in electrical contact with an external electrical connector slot (not shown). The high-frequency line soldering region 12 is disposed on the surface 10 of the substrate 1 and is disposed at the upper edge of the opening 13 or is disposed between the electrical contact region 11 and the upper edge of the opening 13. The opening 13 is positioned proximate to the left (the right, or the middle) of the substrate 1. The low-frequency region 14 is disposed on the surface 10 of the substrate 1 and is disposed between the lower edge of the opening 13 and the lower edge 192 of the substrate 1. The electrical contact region 11 is electrically connected to the low-frequency region 14 through the right (the left or both the right and the left) of the opening 13 and the low-frequency wirings 16 in the middle layer of the substrate 1. The high-frequency wirings 15 each have a high-frequency electrical contact end 151 and a high-frequency line soldering end 152. The high-frequency wirings 15 are disposed on the surface 10 of the substrate 1. The high-frequency electrical contact end 151 is disposed at the electrical contact region 11 so as to be in electrical contact with an external electrical connector slot. The high-frequency line soldering end 152 is disposed at the high-frequency line soldering region 12. Since the high-frequency line soldering region 12 is disposed between the electrical contact region 11 and the low-frequency region 14, the routes of the high-frequency wirings 15 are shortened to thereby decrease attenuation.

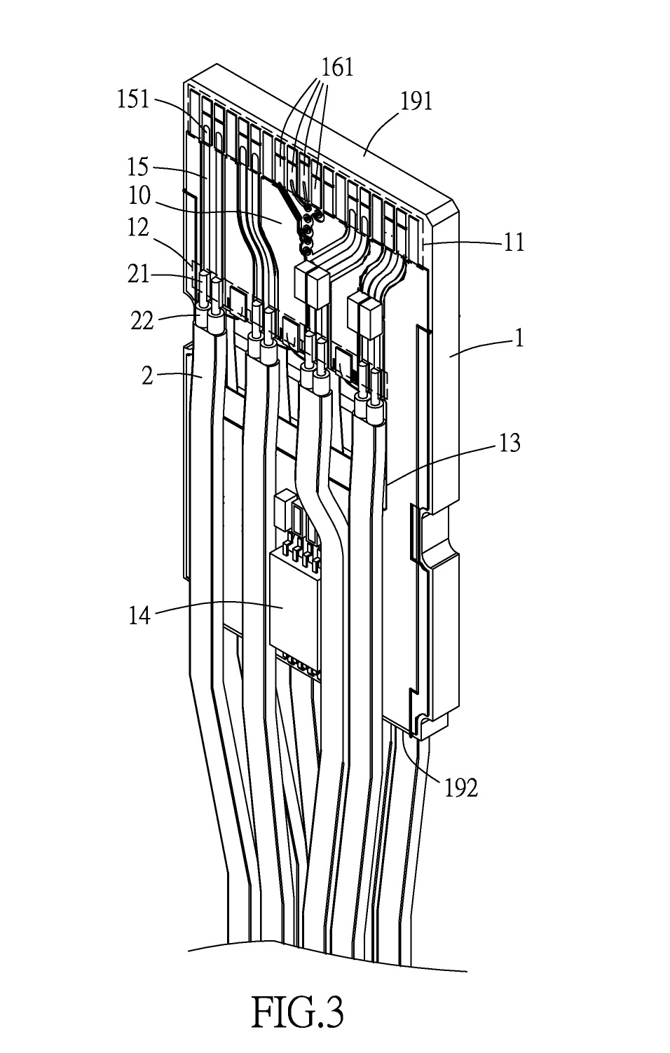

Referring to FIG. 3, the circuit board of the first aspect of the present invention further comprises a plurality of high-frequency lines 2 each having a signal line 21 and an insulating coating 22. The insulating coatings 22 enclose the signal lines 21, respectively. The end portions of the signal lines 21 are exposed from the end portions of the insulating coatings 22, respectively. The end portions of the signal lines 21 are flatly soldered to the high-frequency line soldering ends 152, respectively. The lower edges of the end portions of the insulating coating 22 are received in the opening 13.

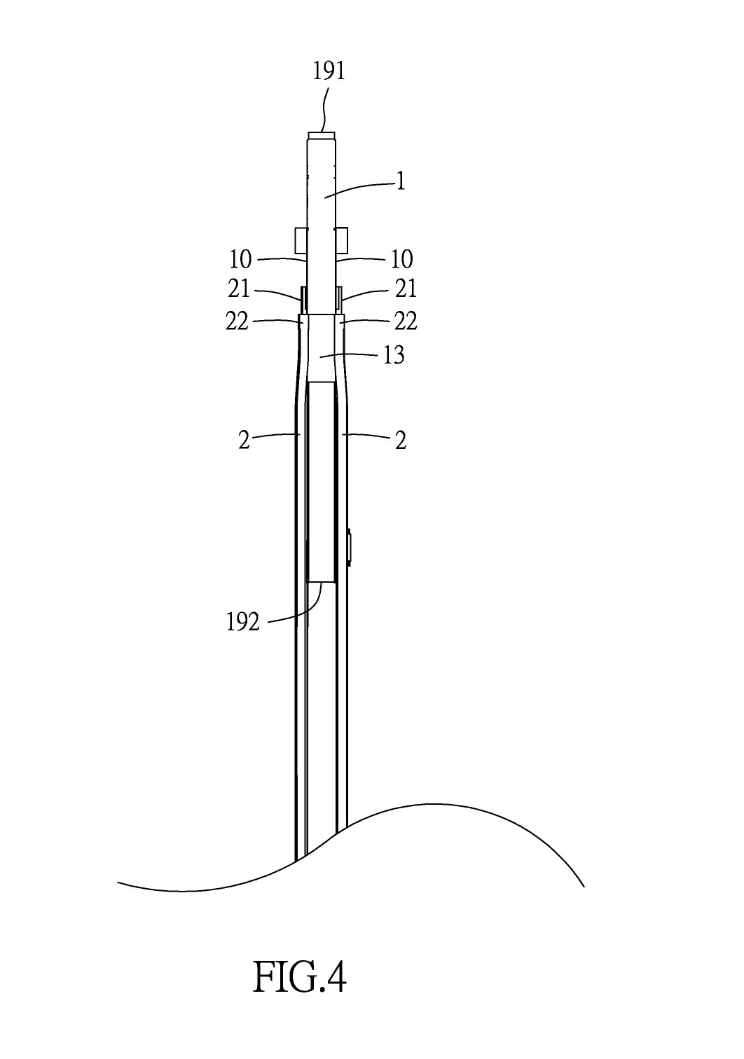

Referring to FIG. 2, FIG. 3, and FIG. 4, since the opening 13 is disposed beneath the high-frequency line soldering region 12, the signal lines 21 of the high-frequency lines 2 are flatly soldered to the high-frequency line soldering ends 152 in the high-frequency line soldering region 12, whereas the lower edges of the insulating coatings 22 of the high-frequency lines 2 are received in the opening 13, so as to prevent the circuit board from warping when the high-frequency lines 2 are soldered to the circuit board.

Referring to FIG. 2, the circuit board of the first aspect of the present invention further comprises a plurality of low-frequency wirings 16 each having a low-frequency electrical contact end 161 and a low-frequency electrical connection end 162. The low-frequency electrical contact end 161 and the low-frequency electrical connection end 162 are disposed on the surface 10 of the substrate 1. The low-frequency wirings 16 are disposed at the middle layer of the substrate 1 and pass the opening 13 laterally (that is, to the right of the opening 13, as shown in FIG. 2). The low-frequency electrical contact ends 161 are disposed at the electrical contact region 11 so as to be in electrical contact with an external electrical connector slot. The low-frequency electrical connection ends 162 are disposed at the low-frequency region 14.

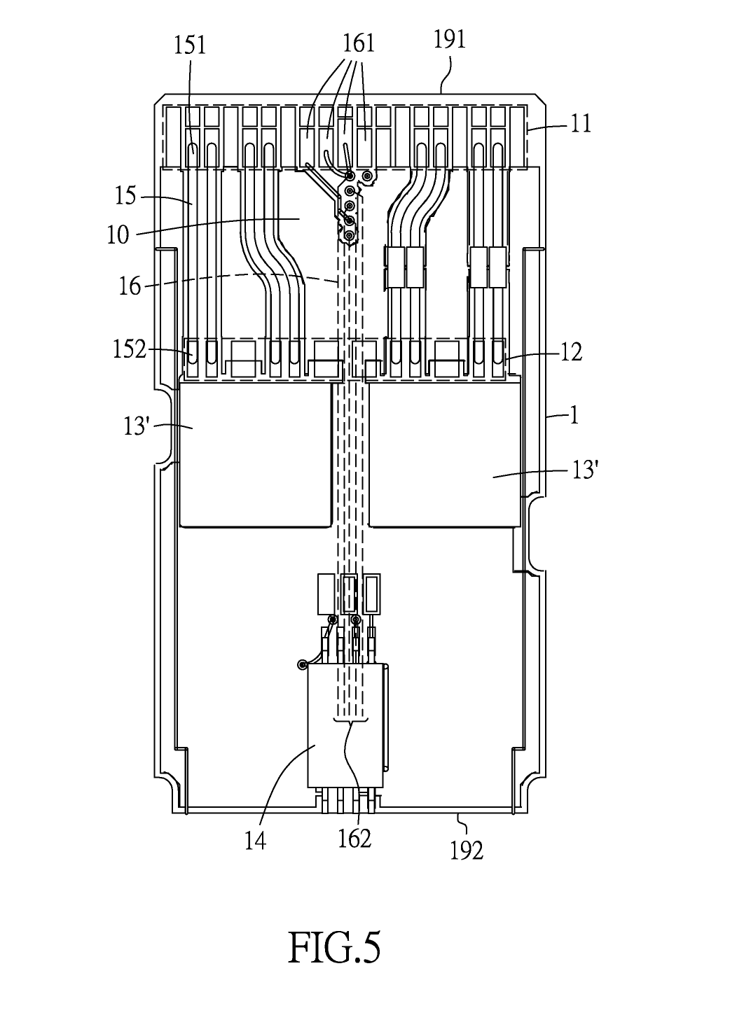

Referring to FIG. 5, the second aspect of the present invention provides another circuit board of an electrical connector, which is different from the circuit board of the first aspect of the present invention in the following: in the second aspect of the present invention, openings 13′ are in the number of two and are arranged transversely, wherein the low-frequency wirings 16 pass between the two openings 13′. Moreover, the quantity of the openings 13′ can increase as needed, whereas the low-frequency wirings 16 can pass the openings 13′ outwardly. Accordingly, when the openings 13′ are provided in the plural, the low-frequency wirings 16 selectively pass between the two openings 13′ or pass the openings 13′ outwardly and uniformly so as to enhance the diversity of the configuration of the low-frequency wirings 16. Similarly, since the high-frequency line soldering region 12 is disposed between the electrical contact region 11 and the low-frequency region 14, the routes of the high-frequency wirings 15 are shortened to thereby decrease attenuation.

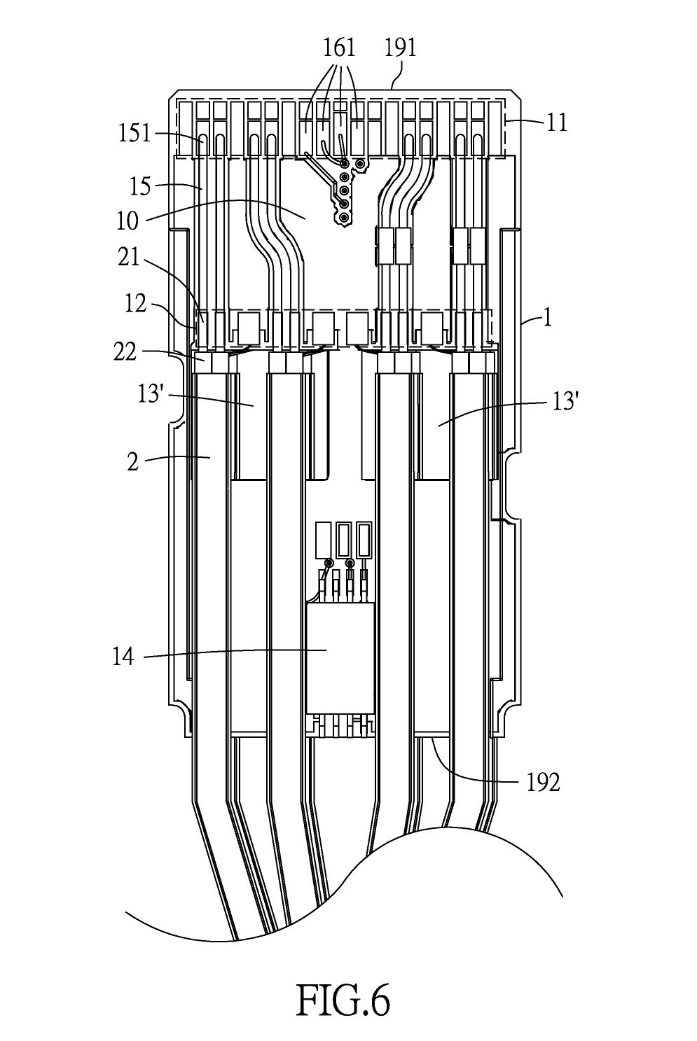

Referring to FIG. 6, the circuit board of the second aspect of the present invention further comprises a plurality of high-frequency lines 2 each having a signal line 21 and an insulating coating 22. The insulating coatings 22 enclose the signal lines 21, respectively, and the end portions of the signal lines 21 are exposed from the end portions of the insulating coatings 22, respectively. The end portions of the signal lines 21 are flatly soldered to the high-frequency line soldering ends 152, respectively. The lower edges of the end portions of the insulating coatings 22 are received in the two openings 13′.

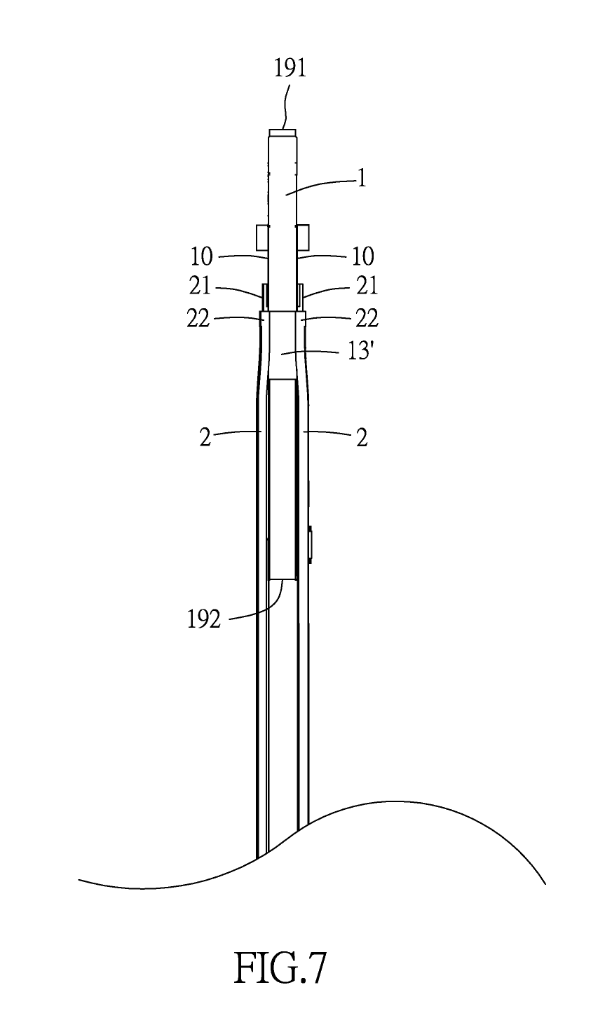

Referring to FIG. 5, FIG. 6, and FIG. 7, since the two openings 13′ are disposed beneath the high-frequency line soldering region 12, the signal lines 21 of the high-frequency lines 2 are flatly soldered to the high-frequency line soldering ends 152 in the high-frequency line soldering region 12, whereas the lower edges of the insulating coatings 22 of the high-frequency lines 2 are received in the two openings 13′, so as to prevent the circuit board from warping when the high-frequency lines 2 are soldered to the circuit board.

Referring to FIG. 2, FIG. 3, FIG. 5, and FIG. 6, regarding the circuit boards of the first and second aspects of the present invention, the high-frequency electrical contact ends 151 and the low-frequency electrical contact ends 161 are arranged transversely and at intervals so as to be in electrical contact with an external electrical connector slot. The high-frequency line soldering ends 152 are arranged transversely and at intervals so as to be soldered to the signal lines 21 of the high-frequency lines 2.

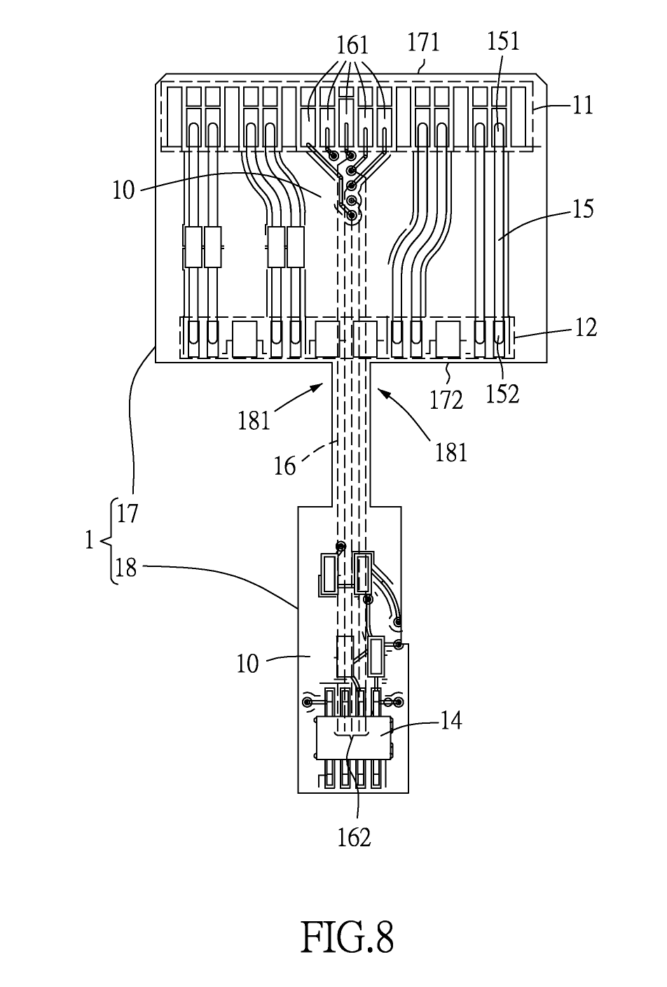

Referring to FIG. 8, the third aspect of the present invention provides yet another circuit board of an electrical connector, comprising a substrate 1 and a plurality of high-frequency wirings 15. The substrate 1 is a bakelite board, fiberglass board, or plastic board, is multilayer, and has at least a middle layer. A plurality of low-frequency wirings 16 is embedded in the middle layer. The substrate 1 has a transverse substrate 17 and a longitudinal substrate 18 which are connected to form a T-shaped configuration. The substrate 1 is flanked by two corners 181. The transverse substrate 17 has thereon an electrical contact region 11 and a high-frequency line soldering region 12 which are arranged longitudinally (that is, in the direction from an upper edge 171 to a lower edge 172 of the transverse substrate 17, as shown in FIG. 8). The electrical contact region 11 is disposed at the upper edge 171 of the surface 10 of the transverse substrate 17 so as to be in electrical contact with an external electrical connector slot (not shown). The high-frequency line soldering region 12 is disposed on the surface 10 of the transverse substrate 17 and is disposed at the lower edge 172 of the transverse substrate 17 or between the electrical contact region 11 and the lower edge 172 of the transverse substrate 17. The two corners 181 are disposed at the lower left of the substrate 1 and the lower right of the substrate 1, respectively. The longitudinal substrate 18 has a low-frequency region 14. The low-frequency region 14 is disposed on the surface 10 of the longitudinal substrate 18 and between the high-frequency line soldering region 12 and the lower edge of the longitudinal substrate 18. The high-frequency line soldering region 12 is disposed between the electrical contact region 11 and the low-frequency region 14. The electrical contact region 11 is electrically connected to the low-frequency region 14 through a portion between the two corners 181 and the low-frequency wirings 16 in the middle layer of the substrate 1. The high-frequency wirings 15 each have a high-frequency electrical contact end 151 and a high-frequency line soldering end 152. The high-frequency wirings 15 are disposed on the surface 10 of the transverse substrate 17. The high-frequency electrical contact end 151 is disposed at the electrical contact region 11 so as to be in electrical contact with an external electrical connector slot. The high-frequency line soldering end 152 is disposed at the high-frequency line soldering region 12. Accordingly, since the high-frequency line soldering region 12 is disposed between the electrical contact region 11 and the low-frequency region 14, the routes of the high-frequency wirings 15 are shortened to thereby decrease attenuation.

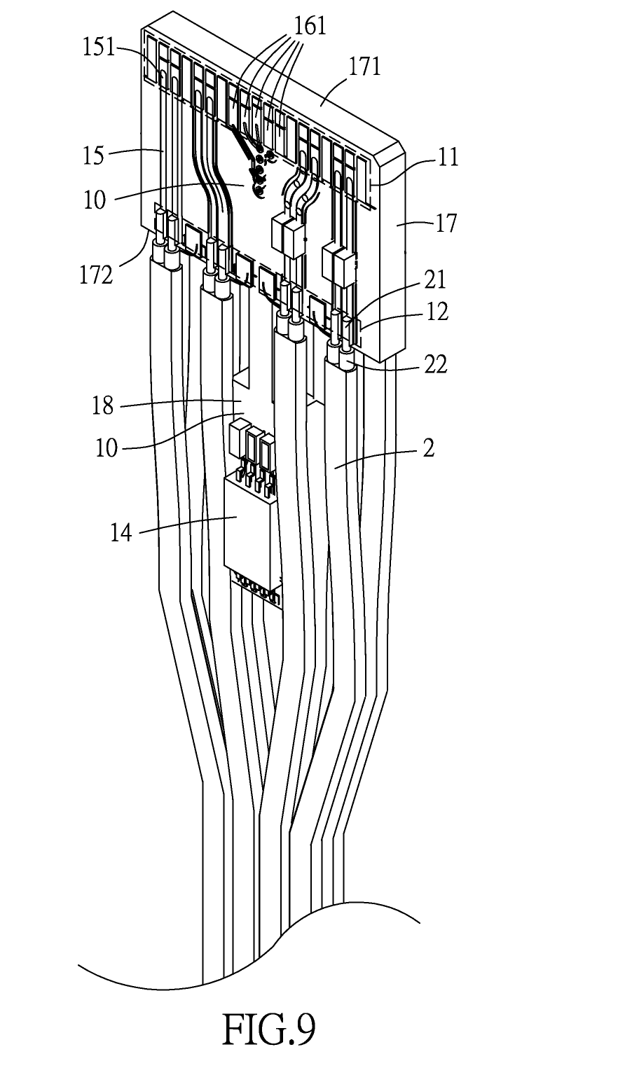

Referring to FIG. 9, the circuit board of the third aspect of the present invention further comprises a plurality of high-frequency lines 2 each having a signal line 21 and an insulating coating 22. The insulating coating 22 encloses the signal lines 21, respectively. The end portions of the signal lines 21 are exposed from the end portions of the insulating coatings 22, respectively. The end portions of the signal lines 21 are flatly soldered to the high-frequency line soldering ends 152, respectively. The lower edges of the end portions of the insulating coatings 22 are received in the two corners 181, respectively.

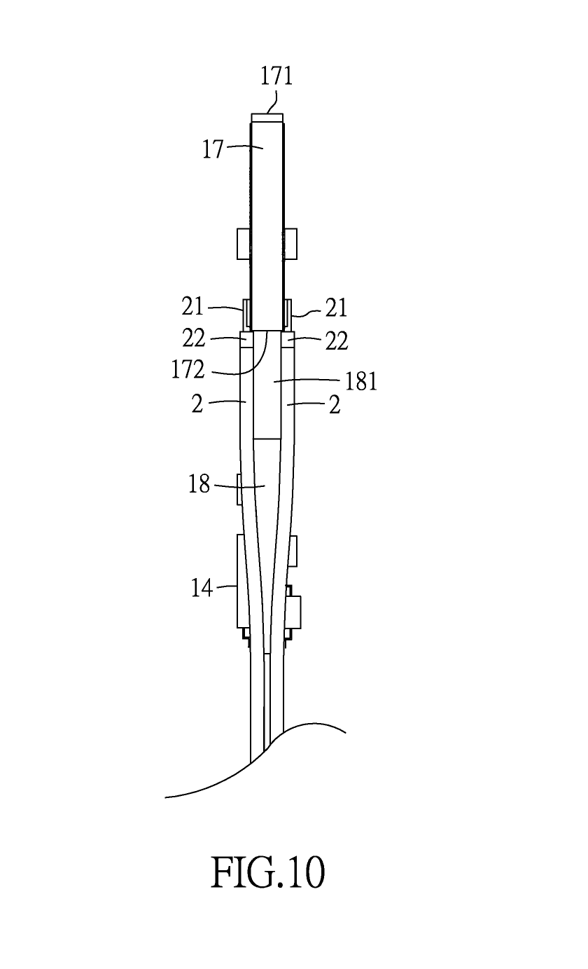

Referring to FIG. 8, FIG. 9, and FIG. 10, since the two corners 181 are disposed beneath the high-frequency line soldering region 12, the signal lines 21 of the high-frequency lines 2 are flatly soldered to the high-frequency line soldering ends 152 in the high-frequency line soldering region 12, and the lower edges of the insulating coatings 22 of the high-frequency lines 2 are received in the two corners 181, so as to prevent the circuit board from warping when the high-frequency lines 2 are soldered to the circuit board. Moreover, due to the two corners 181, rear ends of the high-frequency lines 2 can also be received in the two corners 181 to thereby reduce the thickness of the circuit board when the high-frequency lines 2 are soldered to the circuit board.

Referring to FIG. 8, the circuit board of the third aspect of the present invention further comprises a plurality of low-frequency wirings 16 each having a low-frequency electrical contact end 161 and a low-frequency electrical connection end 162. The low-frequency electrical contact ends 161 and the low-frequency electrical connection ends 162 are disposed on the surface 10 of the transverse substrate 17 and the surface 10 of the longitudinal substrate 18, respectively. The low-frequency wirings 16 are disposed at the middle layer of the substrate 1 and pass between the two corners 181. The low-frequency electrical contact ends 161 are disposed at the electrical contact region 11 so as to be in electrical contact with an external electrical connector slot. The low-frequency electrical connection ends 162 are disposed at the low-frequency region 14.

Referring to FIG. 8 and FIG. 9, regarding the circuit board of the third aspect of the present invention, the high-frequency electrical contact ends 151 and the low-frequency electrical contact ends 161 are arranged transversely and at intervals so as to be in electrical contact with an external electrical connector slot. The high-frequency line soldering ends 152 are arranged transversely and at intervals so as to be soldered to the signal lines 21 of the high-frequency lines 2.

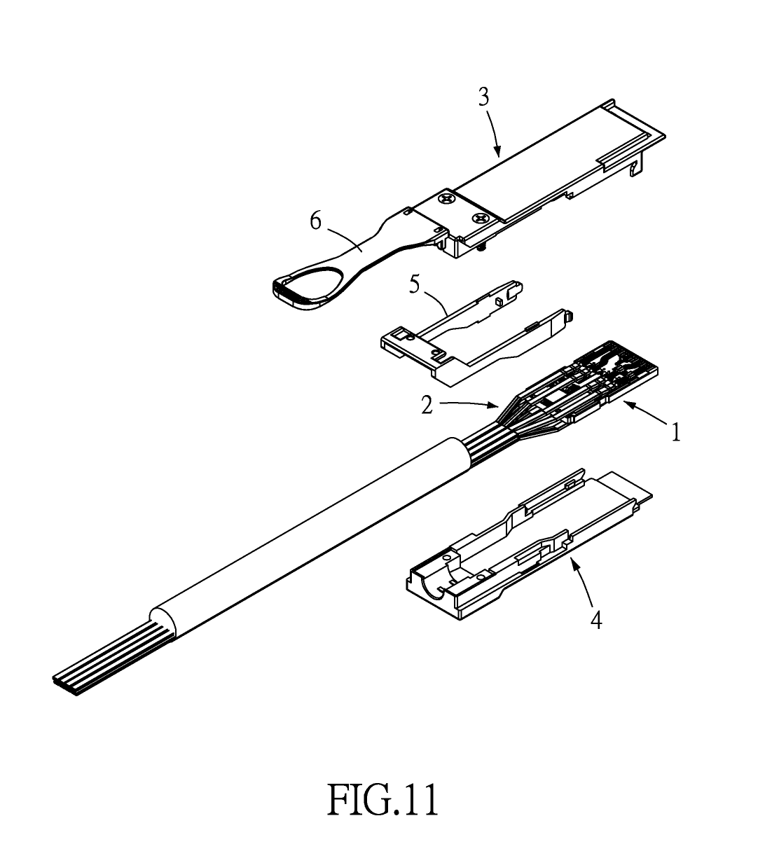

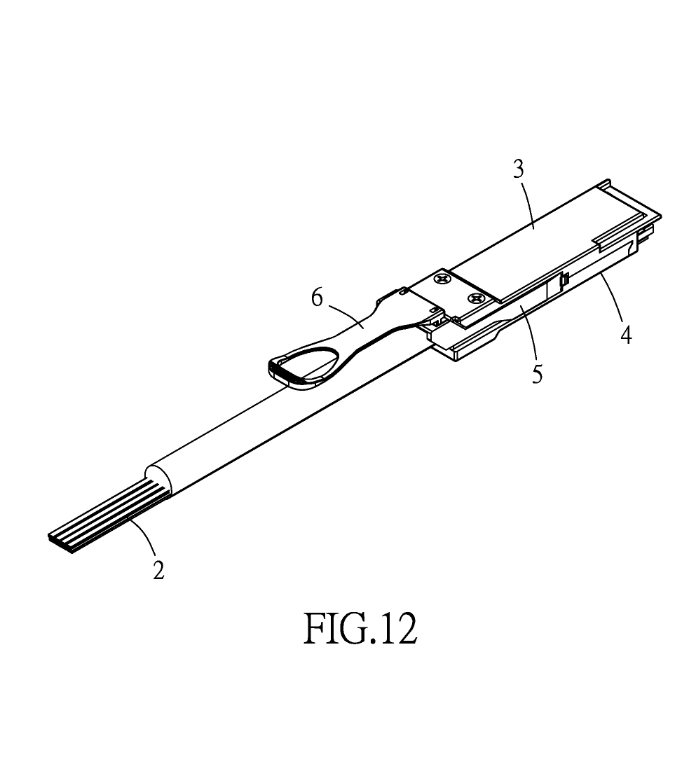

Referring to FIG. 11 and FIG. 12, the circuit board of every aforesaid aspect of the present invention is disposed between an upper casing 3 and a lower casing 4. The upper casing 3 and the lower casing 4 are made of a zinc alloy. The high-frequency lines 2 electrically connected to the circuit board are exposed from the upper casing 3 and the lower casing 4. Moreover, a U-shaped engaging element 5 is outwardly disposed between the upper casing 3 and the lower casing 4. A lug 6 is disposed at the U-shaped engaging element 5. Accordingly, the circuit board of every aspect of the present invention is applicable to an electrical connector.

In conclusion, regarding the circuit board of the first aspect of the present invention, with the high-frequency line soldering region 12 being disposed between the electrical contact region 11 and the low-frequency region 14, the routes of the high-frequency wirings 15 are shortened to thereby decrease attenuation. Moreover, since the openings 13 are disposed beneath the high-frequency line soldering region 12, the signal lines 21 of the high-frequency lines 2 are flatly soldered to the high-frequency line soldering ends 152 in the high-frequency line soldering region 12, whereas the lower edges of the insulating coatings 22 of the high-frequency lines 2 are received in the openings 13, so as to prevent the circuit board from warping when the high-frequency lines 2 are soldered to the circuit board. Regarding the circuit board of the second aspect of the present invention, since the openings 13′ are provided in the plural, the low-frequency wirings 16 selectively pass between the two openings 13′ or pass the openings 13′ outwardly and uniformly so as to enhance the diversity of the configuration of the low-frequency wirings 16. Similarly, regarding the circuit board of the third aspect of the present invention, since the high-frequency line soldering region 12 is disposed between the electrical contact region 11 and the low-frequency region 14, the routes of the high-frequency wirings 15 are shortened to thereby decrease attenuation. Moreover, since the two corners 181 are disposed beneath the high-frequency line soldering region 12, the signal lines 21 of the high-frequency lines 2 are flatly soldered to the high-frequency line soldering ends 152 in the high-frequency line soldering region 12, and the lower edges of the insulating coatings 22 of the high-frequency lines 2 are received in the two corners 181, so as to prevent the circuit board from warping when the high-frequency lines 2 are soldered to the circuit board. Due to the two corners 181, rear ends of the high-frequency lines 2 are also received in the two corners 181 to thereby reduce the thickness of the circuit board when the low high-frequency lines 2 are soldered to the circuit board.

The present invention is disclosed above with preferred embodiments. Nonetheless, persons skilled in the art understand that the embodiments are illustrative rather than restrictive of the present invention. All equivalent changes and replacements of the embodiments are deemed falling into the scope of the present invention. Therefore, legal protection for the present invention must be defined by the appended claims.

What is claimed is:

1. A circuit board of an electrical connector, comprising:
a substrate having an electrical contact region, a high-frequency line soldering region, at least an opening, and a low-frequency region arranged successively and longitudinally, with the electrical contact region disposed at an edge of the substrate, and the electrical contact region electrically connected to the low-frequency region; and
a plurality of high-frequency wirings each having a high-frequency electrical contact end and a high-frequency line soldering end, with the high-frequency wirings disposed at the substrate, the high-frequency electrical contact ends disposed at the electrical contact region, and the high-frequency line soldering ends disposed at the high-frequency line soldering region.

2. The circuit board of claim 1, further comprising a plurality of low-frequency wirings each having a low-frequency electrical contact end and a low-frequency electrical connection end, wherein the low-frequency wirings are disposed at the substrate and pass the openings laterally, with the low-frequency electrical contact ends disposed at the electrical contact region, and the low-frequency electrical connection ends disposed at the low-frequency region.

3. The circuit board of claim 2, wherein the openings are in number of two and are arranged transversely, wherein the low-frequency wirings pass between the openings.

4. The circuit board of claim 2, wherein the high-frequency electrical contact ends and the low-frequency electrical contact ends are arranged transversely and at intervals, wherein the high-frequency line soldering ends are arranged transversely and at intervals.

5. The circuit board of claim 1, further comprising a plurality of high-frequency lines each having a signal line and an insulating coating, wherein the insulating coatings enclose the signal lines, respectively, wherein end portions of the signal lines are exposed from end portions of the insulating coatings, respectively, wherein the end portions of the signal lines are flatly soldered to the high-frequency line soldering ends, wherein the end portions of the insulating coatings are partially disposed in the openings.

6. A circuit board of an electrical connector, comprising:
a substrate having a transverse substrate and a longitudinal substrate connected to each other to form a T-shaped configuration, with the substrate flanked by two corners, wherein the transverse substrate has thereon an electrical contact region and a high-frequency line soldering region longitudinally, with the electrical contact region disposed at an edge of the transverse substrate, wherein the longitudinal substrate has a low-frequency region, wherein the high-frequency line soldering region is disposed between the electrical contact region and the low-frequency region, with the electrical contact region electrically connected to the low-frequency region; and
a plurality of high-frequency wirings each having a high-frequency electrical contact end and a high-frequency line soldering end, with the high-frequency wirings disposed at the transverse substrate, the high-frequency electrical contact ends disposed at the electrical contact region, and the high-frequency line soldering ends disposed at the high-frequency line soldering region.

7. The circuit board of claim 6, further comprising a plurality of low-frequency wirings each having a low-frequency electrical contact end and a low-frequency electrical connection end, being disposed at the substrate, and passing between the corners, wherein the low-frequency electrical contact ends are disposed at the electrical contact region, and the low-frequency electrical connection ends are disposed at the low-frequency region.

8. The circuit board of claim 7, wherein the high-frequency electrical contact ends and the low-frequency electrical contact ends are arranged transversely and at intervals, wherein the high-frequency line soldering ends are arranged transversely and at intervals.

9. The circuit board of claim 6, further comprising a plurality of high-frequency lines each having a signal line and an insulating coating, wherein the insulating coatings enclose the signal lines, respectively, wherein end portions of the signal lines are exposed from end portions of the insulating coatings, respectively, wherein the end portions of the signal lines are flatly soldered to soldering ends of the high-frequency lines, respectively, wherein the end portions of the insulating coatings are partially disposed in the corners, respectively.
